(19) United States
(12) Patent Application Publication
(10) Pub. No.: US 2025/0089177 A1
(43) Pub. Date: Mar. 13, 2025

(54) STRETCHABLE DEVICE

(71) Applicant: Murata Manufacturing Co., Ltd., Nagaokakyo-shi (JP)

(72) Inventors: Toshifumi ASUKAI, Nagaokakyo-Shi (JP); Hayato KATSU, Nagaokakyo-shi (JP)

(21) Appl. No.: 18/955,173

(22) Filed: Nov. 21, 2024

Related U.S. Application Data
(63) Continuation of application No. PCT/JP2023/020308, filed on May 31, 2023.

(30) Foreign Application Priority Data
Jun. 8, 2022 (JP) 2022-093265

(51) Int. Cl. H05K 3/28; H05K 1/02

(52) U.S. Cl. CPC H05K 3/28; H05K 1/0283

(57) ABSTRACT

A stretchable device including: a stretchable substrate having a first main surface and a second main surface; stretchable wiring adjacent the first main surface; a first cover layer covering the first main surface and the stretchable wiring; and a second cover layer covering the second main surface, wherein at least the stretchable substrate includes a discontinuous region, and the first cover layer and the second cover layer are connected to each other in the discontinuous region.

### CROSS REFERENCE TO RELATED APPLICATIONS

The present application is a continuation of International application No. PCT/JP2023/020308, filed May 31, 2023, which claims priority to Japanese Patent Application No. 2022-093265, filed Jun. 8, 2022, the entire contents of each of which are incorporated herein by reference.

### TECHNICAL FIELD

The present disclosure relates to a stretchable device.

### BACKGROUND ART

Conventionally, a stretchable device in which stretchable wiring is mounted on a stretchable substrate has been known. This stretchable device can be used by being attached to a human body.

The stretchable device includes a stretchable substrate, stretchable wiring disposed on one main surface of the stretchable substrate, a stretchable cover covering the one main surface of the stretchable substrate and the stretchable wiring, and an adhesive agent layer provided between the stretchable substrate and the stretchable cover. Patent Document 1 discloses an aspect in which a part of the stretchable substrate has an opening portion, and at least a part of the adhesive agent layer is exposed through the opening portion.

Patent Document 1: Japanese Patent Application Laid-Open No. 2019-75500

### SUMMARY OF THE DISCLOSURE

However, when at least a part of the adhesive agent layer is exposed through the opening portion of the stretchable substrate, the adhesive agent layer exists on one side of the opening portion of the substrate, and the adhesive agent layer does not exist on another side. Therefore, a part (specifically, an inner side surface) of the stretchable substrate forming the opening portion of the substrate may be exposed. Therefore, while air permeability may be improved by the opening portion of the stretchable substrate, moisture may infiltrate the wiring through the part of the exposed stretchable substrate.

Therefore, an object of the present disclosure is to provide a stretchable device capable of improving air permeability and preventing infiltration of moisture into wiring.

To achieve the above object, in one embodiment of

the present disclosure, provided is a stretchable device including: a stretchable substrate having a first main surface and a second main surface; stretchable wiring adjacent the first main surface; a first cover layer covering the first main surface and the stretchable wiring; and a second cover layer covering the second main surface, wherein at least the stretchable substrate includes a discontinuous region, and the first cover layer and the second cover layer are connected to each other in the discontinuous region.

According to the stretchable device according to one embodiment of the present disclosure, it is possible to improve air permeability and prevent infiltration of moisture into the substrate.

### BRIEF EXPLANATION OF THE DRAWINGS

FIG. 1 is a plan view schematically illustrating a stretchable device according to a first embodiment of the present disclosure.

FIG. 2 is a partial sectional view (corresponding to a sectional view between line segments II-II in FIG. 1) schematically illustrating the stretchable device according to the first embodiment of the present disclosure.

FIG. 3 is a partial sectional view schematically illustrating a stretchable device according to a second embodiment of the present disclosure.

FIG. 4 is a partial sectional view schematically illustrating a first modification of a stretchable device according to the second embodiment of the present disclosure.

FIG. 5 is a partial sectional view schematically illustrating a second modification of a stretchable device according to the second embodiment of the present disclosure.

FIG. 6 is a partial sectional view schematically illustrating a stretchable device according to a third embodiment of the present disclosure.

FIG. 7 is a partial sectional view schematically illustrating another example of a stretchable device according to the third embodiment of the present disclosure.

FIG. 8 is a partial sectional view schematically illustrating a first modification of a stretchable device according to the third embodiment of the present disclosure.

FIG. 9 is an enlarged sectional view of a part of FIG. 8.

FIG. 10 is a partial sectional view schematically illustrating a second modification of a stretchable device according to the third embodiment of the present disclosure.

FIG. 11 is an enlarged sectional view of a part of FIG. 10.

FIG. 12 is a plan view schematically illustrating a stretchable device according to a fourth embodiment of the present disclosure.

FIG. 13 is a schematic plan view of a method for producing the stretchable device (a substrate preparation step) according to the first embodiment of the present disclosure.

FIG. 14 is a schematic plan view of the method for producing the stretchable device (a wiring forming step) according to the first embodiment of the present disclosure.

FIG. 15 is a schematic plan view of the method for producing the stretchable device (a step of forming a through hole in the substrate) according to the first embodiment of the present disclosure.

FIG. 16 is a schematic plan view of the method for producing the stretchable device (a step of disposing a cover layer) according to the first embodiment of the present disclosure.

### DESCRIPTION OF THE PREFERRED EMBODIMENTS

Hereinafter, embodiments of the present disclosure will be described in detail with reference to the drawings. In each of the embodiments, a difference from description before the embodiment will be mainly described. Particularly, similar functions and effects achieved by similar configurations will not be mentioned sequentially for each of the embodiments. Among constituent elements in the embodiments below, a constituent element not described in an independent claim will be described as an optional constituent element. Further, sizes and ratios of sizes of constituent elements illustrated in the drawings are not necessarily strict. Further, in the drawings, substantially the same configurations are denoted by the same reference sings, and redundant description may be omitted or simplified.

### First Embodiment

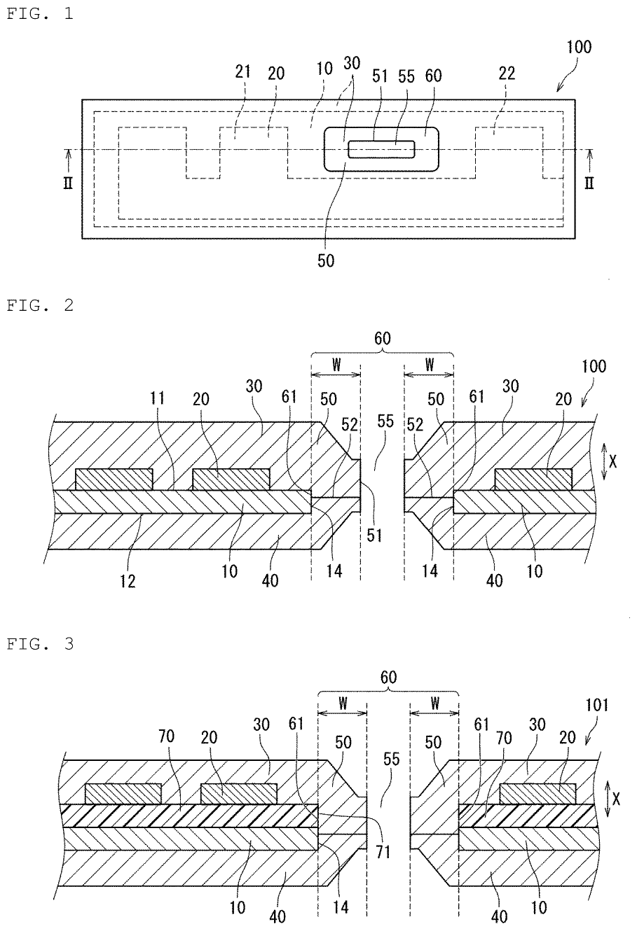

A configuration of a stretchable device 100 according to a first embodiment will be described below with reference to FIGS. 1 and 2.

FIG. 1 is a plan view schematically illustrating the stretchable device according to the first embodiment of the present disclosure. FIG. 2 is a partial sectional view (corresponding to a sectional view between line segments II-II in FIG. 1) schematically illustrating the stretchable device according to the first embodiment of the present disclosure. In the sectional views of the present specification, a thickness direction of a stretchable substrate described later is indicated by a double-headed arrow X.

The stretchable device 100 according to the first embodiment of the present disclosure includes a stretchable substrate 10, stretchable wiring 20, a first cover layer 30, and a second cover layer 40. Specifically, the stretchable substrate 10 has a first main surface 11 and a second main surface 12. The stretchable wiring 20 is adjacent the first main surface 11 of the stretchable substrate 10. The first cover layer 30 covers the first main surface 11 and the stretchable wiring 20 of the stretchable substrate 10. The second cover layer 40 covers the second main surface 12 of the stretchable substrate 10.

Note that a term “adjacent” in the present specification includes a state of being located adjacent a certain element, that is, adjacent a certain element with another object interposed therebetween, a state of being located adjacent a certain element at an interval, and a state of being located immediately adjacent a certain element in contact with the certain element. Therefore, in the present specification, “the stretchable wiring 20 adjacent the first main surface 11 of the stretchable substrate 10” includes the stretchable wiring 20 in a state of being in contact with the first main surface 11 of the stretchable substrate 10 and the elastic wiring 20 in a state of being separated from the first main surface 11 with another member (for example, a resin layer described later) interposed therebetween without being in direct contact with the first main surface 11 of the stretchable substrate 10.

Hereinafter, main constituent elements of the stretchable device 100 according to the first embodiment will be described. After each of the constituent elements is described, characteristic portions of the first embodiment will be described.

### Stretchable Substrate 10

The stretchable substrate 10 is a sheet-shaped or film-shaped stretchable substrate, and includes, for example, a resin material having stretchability. Examples of the resin material of the stretchable substrate 10 include thermoplastic polyurethane (TPU), polyethylene (PE), polystyrene (PS), and polyethylene terephthalate (PET). A thickness of the stretchable substrate 10 is not particularly limited, but is preferably 100 μm or less, and more preferably 50 μm or less, from the viewpoint of not inhibiting stretching of a surface of a living body when the device is attached to the living body. In addition, the thickness of the stretchable substrate 10 is preferably 20 μm or more from the viewpoint of securing a predetermined strength.

### Stretchable Wiring 20

The stretchable wiring 20 contains conductive particles and resin. Examples of a material of the stretchable wiring 20 include a mixture of metal powder of Ag, Cu, Ni, or the like as the conductive particles and an elastomer resin such as a silicone resin. An average diameter of the conductive particles is not particularly limited, but is preferably 0.01 μm to 10 μm. In addition, shapes of the conductive particles are preferably spherical.

A thickness of the stretchable wiring 20 is not particularly limited, but is preferably 100 μm or less, more preferably 50 μm or less. In addition, the thickness of the stretchable wiring 20 is preferably 0.01 μm or more. A line width of the stretchable wiring 20 is not particularly limited, but is preferably 0.1 μm or more and more preferably 10 mm or less. A shape and a number of the stretchable wirings 20 are not particularly limited.

### First Cover Layer 30/Second Cover Layer 40

The first cover layer 30 and the second cover layer 40 may be formed of a resin material having stretchability. For example, the first cover layer 30 and the second cover layer 40 are formed of an ionomer resin, a polyester resin, a styrene resin, an olefin resin, an epoxy resin, an urethane resin, an acrylic resin, or a silicone resin, and are preferably formed of an urethane resin. Examples of the urethane resin include thermoplastic polyurethane (TPU). Examples of the styrene resin include a styrene-butadiene-styrene copolymer resin (SBS). The first cover layer 30 and the second cover 40 may be formed of different materials, but are preferably formed of the same material. Since the first cover layer 30 and the second cover layer 40 are formed of the same material, there is no difference in expansion and contraction due to tension, heat, or the like of the first cover layer 30 and the second cover layer 40, and it is possible to suppress a decrease in reliability associated with unevenness of distortion. In addition, since the same kind of materials are bonded, the layers are well fitted to each other, and a high adhesive strength is improved.

Note that the first cover layer 30 is not necessarily required to be in contact with the stretchable wiring 20 and the first main surface 11 of the stretchable substrate 10. The second cover layer 40 is not necessarily required to be in contact with the second main surface 12 of the stretchable substrate 10.

### Characteristic Portion of First Embodiment

A characteristic portion of the first embodiment will be described below on the basis of contents of each of the constituent elements of the stretchable device 100 described above. In the first embodiment, it is assumed that a discontinuous region 60 is provided to the substrate 10. That is, the substrate 10 forms the discontinuous region 60. In this case, the first embodiment is characterized in that the first cover layer 30 and the second cover layer 40 are connected to each other in the discontinuous region 60.

According to the above characteristic, a connection portion 50 of the first cover layer 30 and the second cover layer 40 connected to each other covers a contour portion 61 of the discontinuous region 60. Specifically, the connection portion 50 between the first cover layer 30 and the second cover layer 40 forming a laminated structure covers an inner side surface 14 of the substrate 10 forming the discontinuous region 60.

In the first embodiment, the stretchable wiring 20 is continuous adjacent the first main surface 11. The connection portion 50 between the first cover layer 30 and the second cover layer 40 is positioned between a first portion 21 of the stretchable wiring 20 and a second portion 22 separately opposed to the first portion 21 (see FIGS. 1 and 2).

In the present embodiment, as illustrated in FIGS. 1 and 2, an aspect is assumed in which the single connection portion 50 including the first cover layer 30 and the second cover layer 40 continues in a circling manner, but the present disclosure is not limited thereto, and two or more connection portions 50 may be positioned adjacent to each other. That is, two or more discontinuous regions 60 provided to the substrate 10 may be positioned adjacent to each other.

From another viewpoint, as illustrated in FIGS. 1 and 2, the connection portion 50 between the first cover layer 30 and the second cover layer 40 may be located inside the contour portion 61 with a position of the contour portion 61 of the discontinuous region 60 as a reference. Specifically, with the position of the contour portion 61 as a reference, an end surface 51 of the connection portion 50 is located inside the contour portion 61. In other words, with a position of the connection portion 50 as a reference, the contour portion 61 of the discontinuous region 60 is located outside the end surface 51 of the connection portion 50.

From still another viewpoint, the first cover layer 30 and the second cover layer 40 overlap with each other in a part of the discontinuous region 60 as viewed in a thickness direction X of the stretchable substrate 10. Specifically, as viewed from the thickness direction X of the stretchable substrate 10, the first cover layer 30 and the second cover layer 40 overlap along the contour portion 61 of the discontinuous region 60, specifically, a contour forming surface of the contour portion 61.

From the above, the presence of the connection portion 50 in the discontinuous region 60 may suppress exposure of the contour portion 61 of the discontinuous region 60 of the stretchable substrate 10, specifically, the inner side surface 14 of the substrate 10 forming the discontinuous region 60. As a result, it is possible to suppress moisture from infiltrate the stretchable wiring 20 from an outside.

By suppressing the infiltration of moisture into the wiring, occurrence of ion migration in the stretchable wiring 20 may be suppressed, and a short circuit of the wiring may be suppressed. As a result, it is possible to improve connection reliability of the stretchable wiring 20.

In addition, since the substrate 10 does not exist in the discontinuous region 60, it is possible to improve the air permeability in the discontinuous region 60 as compared with the other continuous region of the substrate 10. As a result, it is possible to improve the air permeability of the stretchable device 100 as a whole.

From the above, according to the stretchable device 100 of the first embodiment, it is possible to achieve both the improvement in air permeability and the prevention of infiltration of moisture from the outside into the stretchable wiring 20 as a whole.

Note that in the first embodiment, as described above, the first cover layer 30 and the second cover layer 40 overlap in a part of the discontinuous region 60 as viewed from the thickness direction X of the stretchable substrate 10. That is, the connection portion 50 between the first cover layer 30 and the second cover layer 40 is located in a part of the discontinuous region 60.

In this case, in a remaining portion of the discontinuous region 60, the connection portion 50 is not located, while a through hole 55 penetrating the first cover layer 30 and the second cover layer 40 is positioned. Since the through hole 55 is a physical gap portion, it is possible to further improve the air permeability of the stretchable device 100.

Further, as illustrated in FIG. 2, it is preferable that a connection surface 52 (or a contact surface) where the first cover layer 30 and the second cover 40 layer are connected to each other in the thickness direction X of the stretchable substrate 10 overlaps an inside of the discontinuous region 60, that is, is located inside the discontinuous region 60. With such a structure, movement of the connection surface 52 from the discontinuous region 60 to another region may be suppressed by the inner side surface 14 of the stretchable substrate 10 forming the discontinuous region 60. Thus, it is possible to improve reliability of the connection.

More preferably, the connection surface 52 may be disposed between both the main surfaces of the stretchable substrate 10 in sectional view. It is conceivable that the stretchable device 100 expands and contracts to the left and right at the time of use. At this time, if the connection surface 52 is not between both the main surfaces of the stretchable substrate 10 in the thickness direction X of the stretchable substrate 10, the connection surface moves left and right, and there is a possibility that reliability of the connection surface 52 may be deteriorated. In addition, in a case where the connection surface 52 is flush with the upper main surface of the stretchable substrate 10, movement of the lower second cover layer 40 can be suppressed, but movement of the upper first cover layer 30 is hardly suppressed, and there may be a possibility that it is difficult to improve the connection reliability. With the above more preferable structure, the inner side surface 14 of the stretchable substrate further suppresses the movement of the connection surface 52 from the discontinuous region 60 to another region. Thus, it is possible to improve the reliability of the connection.

In addition, from the viewpoint of further improving the air permeability of the stretchable device 100, each of the first cover layer 30 and the second cover layer 40 preferably has a higher moisture permeability (corresponding to a water vapor transmittance) than the stretchable substrate 10 alone or a stretchable wiring substrate including the stretchable substrate 10 and the stretchable wiring 20.

The moisture permeability of each of the first cover layer 30 and the second cover layer 40 is larger than 100 g/(m²·24 h), and may be 150 g/(m²·24 h) or more, 200 g/(m²·24 h) or more, 250 g/(m²·24 h) or more, 300 g/(m²·24 h) or more, 350 g/(m²·24 h) or more, or 400 g/(m²·24 h) or more on the basis of JISZ0208 (a moisture permeability test method (a cup method) for a moisture proof wrapping material). For example, the moisture permeability of each of the first cover layer 30 and the second cover layer 40 may be 250 g/(m²·24 h).

An elastic modulus of each of the first cover layer 30 and the second cover layer 40 is preferably smaller than an elastic modulus of the stretchable substrate 10. Since the stretchable device 100 may expand and contract at the time of use, when a cover layer having a high elastic modulus is used, there is a possibility that discomfort is given to a human body during stretching. By setting the elastic modulus of each of these cover layers to be lower than the elastic modulus of the stretchable substrate 10, the discomfort felt by the user at the time of using the stretchable device 100 can be reduced.

For example, it is preferable that the elastic modulus of each of the first cover layer 30 and the second cover layer 40 is 1.0×10\hat{ }6 Pa or more from the viewpoint of preventing inhibition of expansion and contraction at the time of expansion and contraction, and is 1.0×10\hat{ }8 Pa or less from the viewpoint of suppressing deformation. A method for measuring the elastic modulus is not particularly limited, and examples thereof include dynamic viscoelasticity measurement. In a case where each of the cover layers 30, 40 may be configured of a plurality of members, the elastic modulus can be calculated by performing measurement in the same manner and comparing average values.

It is preferable that a thickness of each of the first cover layer 30 and the second cover layer 40 is 30 μm or more from the viewpoint of suppressing moisture infiltration, that is, waterproofing, and is 200 μm or less from the viewpoint of preventing inhibition of expansion and contraction at the time of expansion and contraction.

From the viewpoint of preferable peeling prevention of the two cover layers 30, 40, a thickness of the connection portion 50 including the two cover layers 30, 40 may be larger than the thickness of the stretchable substrate 10. Alternatively, from the viewpoint of improving the air permeability of the stretchable device 100, the thickness of the connection portion 50 including the two cover layers 30, 40 may be smaller than the thickness of the stretchable substrate 10.

In the discontinuous region 60 of the substrate 10 (or a laminate of a substrate 10 and a resin layer in a second and subsequent embodiments) to which the connection portion 50 may be provided, as viewed from the thickness direction X of the stretchable substrate 10, a total planar size of the discontinuous region 60 may be 10% or more of a planar size of the stretchable substrate 10 from the viewpoint of ensuring the air permeability, and may be 90% or less from the viewpoint of ensuring a predetermined strength of the stretchable device. The total planar size of the discontinuous region 60 is preferably 20% to 80%, and more preferably 30% to 70% of the planar size of the stretchable substrate 10.

In addition, a ratio between a width dimension W of the connection portion 50 in sectional view and a thickness dimension of the inner side surface 14 of the substrate 10 may be 1:1 from the viewpoint of preferable covering of the inner side surface 14 of the substrate 10. In addition, the width dimension W of the connection portion 50 in sectional view may be 0.1 mm or more, preferably 0.5 mm or more, and more preferably 1 mm or more from the viewpoint of preferable covering of the inner side surface 14 of the substrate 10.

In another embodiment described later, an adhesive layer may be disposed in an interface region between the first cover layer 30 and a mating member (the stretchable wiring 20, the second cover layer 40, and the like) connected to the first cover layer 30. Further, an adhesive layer may be disposed in an interface region between the second cover layer 40 and a mating member (the stretchable substrate 10, the first cover layer 30, and the like) connected to the second cover layer 40.

However, this adhesive layer is not necessarily required, and in the present embodiment, it is possible to adopt a configuration in which a surface itself of each of the cover layers 30, 40 on the interface region side with the mating member (the stretchable wiring 20, the second cover layer 40, and the like) has adhesiveness. In this case, as illustrated in FIG. 2, a configuration in which the first cover layer 30 and the second cover layer 40 are in contact with each other in the discontinuous region 60 of the stretchable substrate 10 in the thickness direction X of the stretchable substrate 10 can be adopted.

Hereinafter, a method for producing the stretchable device 100 according to the first embodiment (corresponding to a basic embodiment) will be described with reference to FIGS. 13 to 16.

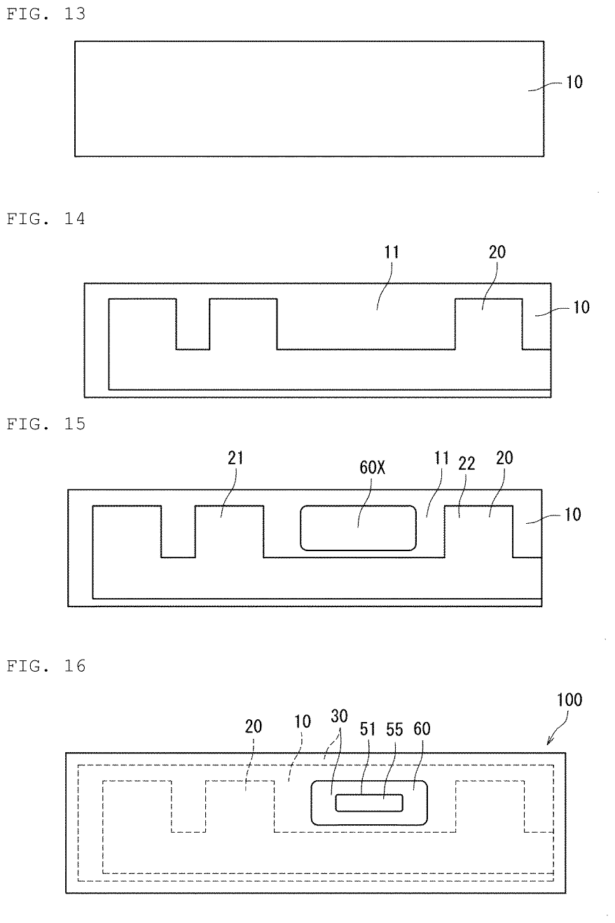

First, the substrate 10 is prepared (see FIG. 13). After the preparation of the substrate 10, the stretchable wiring 20 in a continuous form is formed adjacent the first main surface 11 of the substrate 10 (see FIG. 14). After the formation of the stretchable wiring 20, a through hole 60X (may also be referred to as an opening portion) is formed in a predetermined portion of the substrate 20 located between the first portion 21 of the stretchable wiring 20 in the continuous form and the second portion 22 separately opposed to the first portion 21 (see FIG. 15).

The through hole 60X can be formed by punching, laser processing, or the like. An opening diameter of the through hole 60x may be 0.1 mm or more from the viewpoint of processing, and may be 10 mm or less from the viewpoint of layout restriction of the stretchable device 100 to be obtained and avoidance of increase in device size. A planar shape of the through hole 60X may be, for example, a perfect circle, an ellipse, a polygon, or the like.

After the formation of the through-hole 60x, the first cover layer 30 is disposed so as to cover the first main surface 11 and the stretchable wiring 20 of the substrate 10 with the through hole 60x, and the second cover layer is disposed so as to cover the second main surface of the substrate 10 with the through hole 60X. Thereafter, in the first embodiment, the through hole 55 is further formed in the connection portion between the first cover layer 30 and the second cover layer 40 disposed so as to close the through hole 60X of the substrate.

As described above, the stretchable device 100 according to the first embodiment (corresponding to the basic embodiment) can be manufactured.

Note that when a stretchable device of a third embodiment described later is produced, the through hole 55 is not further formed in the connection portion between the first cover layer 30 and the second cover layer 40.

### Second Embodiment

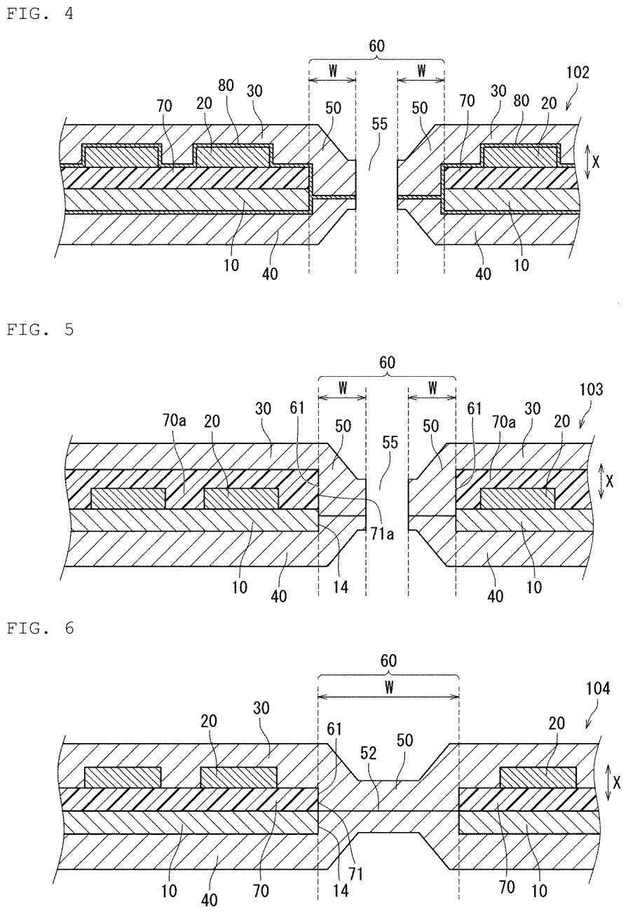

Hereinafter, a configuration of a stretchable device 101 according to a second embodiment will be described with reference to FIG. 3. The second embodiment is different from the first embodiment in that the stretchable device 101 further includes a resin layer 70.

FIG. 3 is a partial sectional view schematically illustrating the stretchable device according to the second embodiment of the present disclosure.

As illustrated in FIG. 3, the resin layer 70 may be located between the first main surface 11 of the stretchable substrate 10 and the stretchable wiring 20. In this case, since the resin layer 70 may be located between the first main surface 11 of the stretchable substrate 10 and the stretchable wiring 20, a surface of the stretchable wiring 2 on a side closest to the stretchable substrate 10 may be in contact with the resin layer 70.

In addition, since the resin layer 70 may also constitute the contour portion 61 of the discontinuous region 60 in addition to the stretchable substrate 10, an inner side surface 71 of the resin layer 70 is covered with the connection portion 50 between the first cover layer 30 and the second cover layer 40 forming the laminated structure. In addition, the resin layer 70 covers the first main surface 11 of the stretchable substrate 10 so as to be continuously in contact therewith.

From the above, it is possible to more preferably suppress the infiltration of moisture into the stretchable wiring 20 as compared with the first embodiment not having the resin layer 70.

### First Modification of Second Embodiment

Hereinafter, a configuration of a first modification of a stretchable device 102 according to the second embodiment will be described with reference to FIG. 4. The first modification of the second embodiment is different from the form illustrated in FIG. 3 in that the stretchable device 102 further includes an adhesive layer 80.

FIG. 4 is a partial sectional view schematically illustrating the first modification of the stretchable device according to the second embodiment of the present disclosure.

As illustrated in FIG. 4, the adhesive layer 80 may be disposed in the interface region between the first cover layer 30 and the mating member (the stretchable wiring 20, the second cover layer 40, and the like) connected to the first cover layer 30 in the thickness direction X of the stretchable substrate 10. Further, the adhesive layer 80 may be disposed in the interface region between the second cover layer 40 and the mating member (the stretchable substrate 10, the first cover layer 30, and the like) connected to the second cover layer 40 in the thickness direction X of the stretchable substrate 10.

According to the above disposition, peeling of the first cover layer 30 and the second cover layer 40 can be suppressed, and misalignment of both the cover layers 30, 40 can be suppressed. As a result, it is possible to more preferably improve the air permeability and prevent infiltration of moisture into the wiring in the stretchable device 102, which have been described in the first embodiment.

The adhesive layer 80 may include a pressure sensitive adhesive or the like. The pressure sensitive adhesive is not particularly limited as long as it can be laminated adjacent the stretchable substrate 10 and generally used. For example, as the pressure sensitive adhesive, a rubber adhesive, an acrylic adhesive, or a silicone adhesive can be used. When the pressure sensitive adhesive is used, the cover layers 30, 40 and the mating members can be bonded to each other at a relatively low temperature, so that change in quality and distortion of the stretchable substrate 10 by using excessive heat and UV energy can be prevented.

### Second Modification of Second Embodiment

Hereinafter, a configuration of a second modification of a stretchable device 103 according to the second embodiment will be described with reference to FIG. 5. The second modification of the second embodiment is different from the first embodiment in that the stretchable device 103 further includes a resin layer 70a.

FIG. 5 is a partial sectional view schematically illustrating the second modification of the stretchable device according to the second embodiment of the present disclosure.

As illustrated in FIG. 5, the resin layer 70a may be located so as to cover the first main surface 11 of the stretchable substrate 10 and the stretchable wiring 20 adjacent the first main surface 11. In this case, the resin layer 70a may be disposed so as to cover an entire outer surface of the stretchable wiring 20.

In addition, since the resin layer 70a may also constitute the contour portion 61 of the discontinuous region 60 in addition to the stretchable substrate 10, an inner side surface 71a of the resin layer 70a is also covered with the connection portion 50 between the first cover layer 30 and the second cover layer 40 forming the laminated structure. In addition, the resin layer 70a is in contact with the first main surface 11 of the stretchable substrate 10 except for the disposition location of the wiring 20. From the above, it is possible to more preferably suppress the infiltration of moisture into the stretchable wiring 20 as compared with the first embodiment not including the resin layer 70a.

Note that in the second embodiment, the resin layers 70, 70a may be formed by printing a resin material or a mixture of a resin material and an inorganic material.

Examples of the resin material include elastomer resins such as urethane, styrene, olefin, silicone, fluorine, nitrile rubber, latex rubber, vinyl chloride, ester, and amide resins, epoxy, phenol, acrylic, polyester, imide, rosin, cellulose, polyethylene terephthalate, polyethylene naphthalate, and polycarbonate resins. Note that the resin layer 70 may not be a single material. In addition, the resin layer 70 may be formed of a plurality of layers.

A thickness of the resin layer 70 is not particularly limited, but is preferably 100 μm or less, and more preferably 50 μm or less from the viewpoint of not inhibiting the expansion and contraction of the surface of the living body when the device is attached to the living body. The thickness of the resin layer 70 is preferably 10 μm or more from the viewpoint of securing a predetermined strength.

That is, a total thickness of the substrate 10 and the resin layer 70 is preferably 200 μm or less, and more preferably 100 μm or less. In addition, the total thickness of the substrate 10 and the resin layer 70 is preferably 30 μm or more from the viewpoint of securing a predetermined strength.

### Third Embodiment

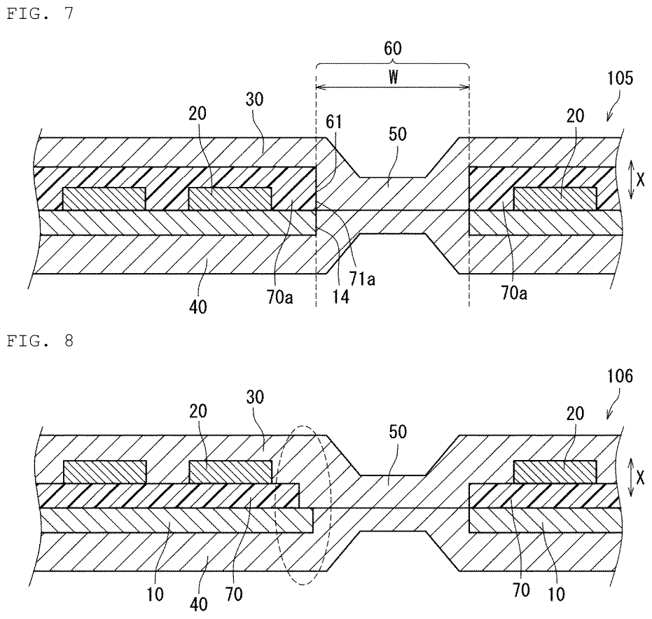

Configurations of stretchable devices 104, 105 according to a third embodiment will be described below with reference to FIGS. 6 and 7.

FIG. 6 is a partial sectional view schematically illustrating the stretchable device according to the third embodiment of the present disclosure. FIG. 7 is a partial sectional view schematically illustrating another example of the stretchable device according to the third embodiment of the present disclosure.

The third embodiment is different from the second embodiment in that the connection portion 50 between the first cover layer 30 and the second cover layer 40 is located in the entire discontinuous region 60 as viewed in the thickness direction X of the stretchable substrate 10.

According to the configuration of the third embodiment, the entire discontinuous region 60 may be filled with the connection portion 50 between the first cover layer 30 and the second cover layer 40. As a result, as compared with the first embodiment and the second embodiment, since there is no physical gap portion in the discontinuous region 60, the exposure of the contour portion 61 of the discontinuous region 60 of the stretchable substrate 10, specifically, the inner side surface 14 of the substrate 10 and inner side surfaces 71, 71a of the resin layer 70 forming the discontinuous region 60 may be more preferably suppressed. Therefore, infiltration of moisture from an outside of each of the stretchable devices 104, 105 into the wiring may be more preferably suppressed, and occurrence of ion migration in the stretchable wiring 20 can be more preferably suppressed.

As described above, the first cover layer 30 and the second cover layer 40 each have a predetermined water vapor permeability. Therefore, though the connection portion 50 between the first cover layer 30 and the second cover layer 40 fills the entire discontinuous region 60 (corresponding to the opening portion of the stretchable substrate 10), the air permeability can be improved as compared with a case where the discontinuous region 60 is absent, that is, a case where there is no opening portion in the stretchable substrate 10. Reliability of the stretchable device is improved because an adhesive force of the upper and lower cover layers is improved as compared with the case where the cover layers have the opening portion.

As described above, it is preferable that the connection surface 52 (or the contact surface) where the first cover layer 30 and the second cover layer 40 are in contact with each other in the thickness direction X of the stretchable substrate 10 overlaps an inside of the discontinuous region 60. When the inner side surface 14 of the stretchable substrate 10 and the inner side surface 71 of the resin layer 70 are flush with each other as illustrated in FIG. 6, the connection surface 52 and the upper main surface of the stretchable substrate 10 may be disposed at the same position in the thickness direction X of the stretchable substrate 10. The inner side surface 71 of the resin layer 70 restrains the connection surface 52 from greatly moving from the discontinuous region 60 to another region. In addition, when the upper main surface of the resin layer 70 is flush with the connection surface 52, an effect of improving the connection reliability may be reduced, and thus it is preferable that the connection surface 52 overlaps the resin layer 70 in addition to the inside of the discontinuous region 60 in the thickness direction X of the stretchable substrate 10.

### First Modification of Third Embodiment

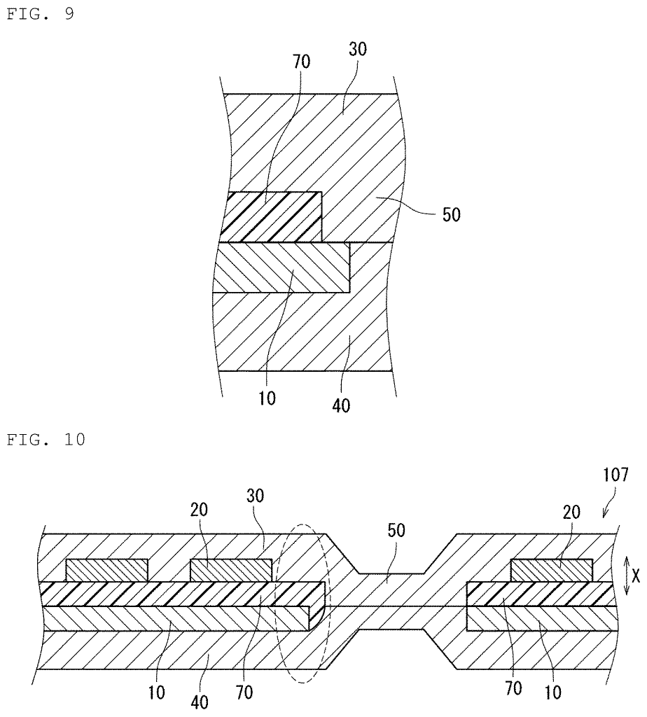

Hereinafter, a configuration of a first modification of a stretchable device 106 according to the third embodiment will be described with reference to FIGS. 8 and 9.

FIG. 8 is a partial sectional view schematically illustrating the first modification of the stretchable device according to the third embodiment of the present disclosure. FIG. 9 is an enlarged sectional view of a part of FIG. 8.

As illustrated in FIGS. 8 and 9, a stepped structure is provided by the inner side surface 14 (corresponding to an end surface) of the stretchable substrate 10 and the inner side surface 71 (corresponding to an end surface) of the resin layer 70. Specifically, in sectional view, the inner side surface of the stretchable substrate 10 may be located inside the inner side surface of the resin layer 70 with a position of the inner side surface of the resin layer 70 as a reference. In other words, a region of the stretchable substrate 10 that does not overlap the resin layer 70 when viewed from the thickness direction is in contact with the first cover layer 30 and/or the second cover layer 40 that are constituent elements of the connection portion 50.

In this case, as described above, since the stretchable substrate 10, the resin layer 70, and the cover layers 30, 40 are different in material from one another, when the stretchable device 106 is used, stretch rates of a laminated portion of the stretchable substrate 10, the resin layer 70, and the cover layers 30, 40, a laminated portion of the stretchable substrate 10 and the cover layers 30, 40, and a portion where only the cover layers 30, 40 exist may be increased in this order.

As a result, by intentionally disposing the laminated portion of the stretchable substrate 10 and the cover layers 30, 40, a portion having an intermediate stretch rate may be disposed. As a result, as compared with the case where the laminated portion of the stretchable substrate 10 and the cover layer 30 is absent, that is, the case where the inner side surface 14 of the stretchable substrate 10 and the inner side surface 71 of the resin layer 70 have a substantially flush structure, concentration of stress that may occur during use of the stretchable device 106 can be alleviated. As a result, it is possible to improve air permeability of the stretchable device 106.

### Second Modification of Third Embodiment

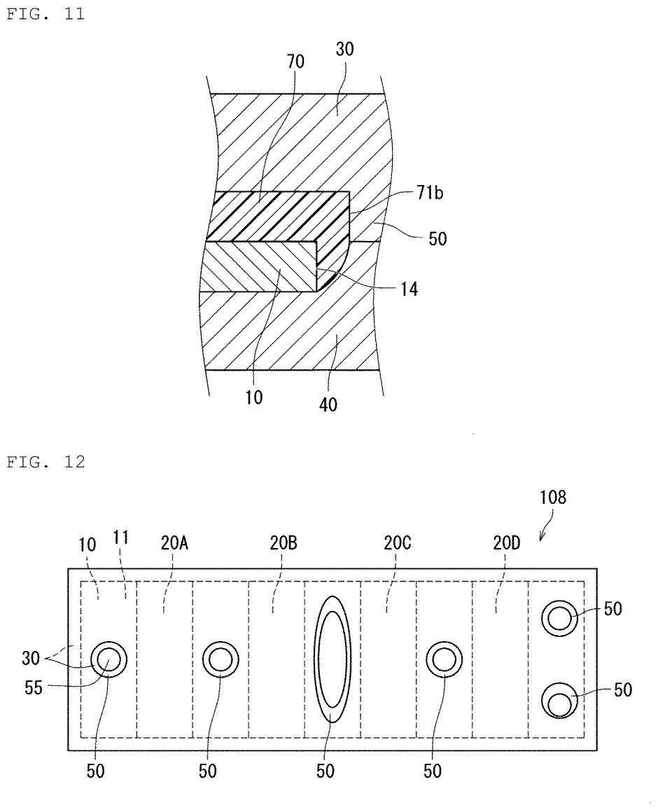

A configuration of a second modification of a stretchable device 107 according to the third embodiment will be described below with reference to FIGS. 10 and 11.

FIG. 10 is a partial sectional view schematically illustrating the second modification of the stretchable device according to the third embodiment of the present disclosure. FIG. 11 is an enlarged sectional view of a part of FIG. 10.

As illustrated in FIGS. 10 and 11, in the discontinuous region of the stretchable substrate 10 and the resin layer 70, the inner side surface of the stretchable substrate 10 may be located outside the inner side surface of the resin layer 70 with the position of the inner side surface of the resin layer 70 as a reference. Furthermore, in other words, a region of the resin layer 70 that does not overlap the stretchable substrate 10 as viewed from the thickness direction is in contact with the first cover layer 30 and/or the second cover layer 40, which are constituent elements of the connection portion 50.

In this case, as described above, since the stretchable substrate 10, the resin layer 70, and the cover layers 30, 40 are different in material from one another, when the stretchable device 106 is used, stretch rates of a laminated portion of the stretchable substrate 10, the resin layer 70, and the cover layers 30, 40, a laminated portion of the resin layer 70 and the cover layers 30, 40, and a portion where only the cover layers 30, 40 exist may be increased in this order.

As a result, by intentionally disposing the laminated portion of the resin layer 70 and the cover layers 30, 40, a portion having an intermediate stretch rate may be disposed. As a result, as compared with the case where the laminated portion of the resin layer 70 and the cover layers 30, 40 is absent, that is, a case where the inner side surface 14 of the stretchable substrate 10 and the inner side surface of the resin layer 70 have a substantially flush structure, concentration of stress that may occur during use of the stretchable device 106 can be alleviated. As described above, a strength of the stretchable device 107 can be improved.

In addition, when the inner side surface of the stretchable substrate 10 may be located outside the inner side surface of the resin layer 70 with the position of the inner side surface of the resin layer 70 as a reference, the resin layer 70 may be located adjacent the stretchable substrate 10 and inside the inner side surface of the stretchable substrate 10. Therefore, a portion corresponding to an inner side surface 71b of the resin layer 70 may hang downward at the stage of producing the stretchable device or the like.

As a result, the inner side surface 71b of the finally formed resin layer 70 can cover at least a part of the inner side surface 14 of the stretchable substrate 10. Therefore, infiltration of moisture from an outside of the stretchable device 107 into the stretchable wiring 20 can be more preferably suppressed, and occurrence of ion migration in the stretchable wiring 20 may be more preferably suppressed.

In the case of the structure as described above, it is obvious that the inner side surface 71b of the resin layer can suppress the connection surface 52 from greatly moving from the discontinuous region 60 to another region. Note that in a structure in which the inner side surface of the resin layer does not hang downward, the same effect of suppressing the movement of the connection surface 52 can be provided by the inner side surface.

### Fourth Embodiment

Hereinafter, configurations of the stretchable devices 104, 105 according to a fourth embodiment will be described with reference to FIG. 12.

FIG. 12 is a plan view schematically illustrating the stretchable device according to the fourth embodiment of the present disclosure.

The fourth embodiment is different from the first embodiment in that a plurality of stretchable wirings are used. Specifically, in the fourth embodiment, a plurality of stretchable wirings 20A to 20D are separately opposed to one another, and the connection portion 50 between the first cover layer 30 and the second cover layer may be positioned in a predetermined region (corresponding to the first main surface 11 of the substrate 10, or the resin layer adjacent the first main surface 11) between adjacent stretchable wirings.

Preferably, from the viewpoint of achieving both “improvement in air permeability” and “prevention of infiltration of moisture from an outside into each of the plurality of stretchable wirings 20A to 20D” in the stretchable device 108, the stretchable wirings and the connection portion 50 between the first cover layer 30 and the second cover layer may be alternately arranged.

Note that each of the embodiments and modifications is an example, and the present disclosure is not limited to each of the embodiments and the modifications. In addition, each of the drawings is an example of the constituent elements, and does not limit a shape. Further, partial replacement or combination of the configurations illustrated in the different embodiments and modifications is possible.

In addition, in each of the embodiments, a gap may be provided between the cover layers (the first cover layer 30/the second cover layer 40) and the stretchable substrate 10 and/or the wiring 20. For example, gaps may be provided between the first cover layer 30 and the stretchable substrate 10, between the first cover layer 30 and the wiring 20, and between the second cover layer 40 and the stretchable substrate 10. The gaps function as buffers when the stretchable device expands and contracts. By providing the above gaps, it is possible to improve the air permeability while maintaining reliability during expansion and contraction.

Note that aspects of a stretchable device according to the present disclosure are as described below.
<1> A stretchable device including: a stretchable substrate having a first main surface and a second main surface; stretchable wiring adjacent the first main surface; a first cover layer covering the first main surface and the stretchable wiring; and a second cover layer covering the second main surface, wherein at least the stretchable substrate includes a discontinuous region, and the first cover layer and the second cover layer are connected to each other in the discontinuous region.
<2> The stretchable device according to <1>, wherein a connection portion between the first cover layer and the second cover layer connected to each other covers a contour portion of the discontinuous region.
<3> The stretchable device according to <1> or <2>, wherein the first cover layer and the second cover layer form a laminated structure in the discontinuous region.
<4> The stretchable device according to any one of <1> to <3>, wherein the connection portion between the first cover layer and the second cover layer connected to each other is located inside the contour portion of the discontinuous region.
<5> The stretchable device according to any one of <1> to <4>, wherein the first cover layer and the second cover layer overlap in at least a part of the discontinuous region as viewed from a thickness direction of the stretchable substrate.
<6> The stretchable device of any one of <1> to <5>, wherein the first cover layer and the second cover layer overlap along the contour portion of the discontinuous region.
<7> The stretchable device according to any one of <1> to <5>, wherein the connection portion between the first cover layer and the second cover layer is located in the entire discontinuous region as viewed from the thickness direction of the stretchable substrate.
<8> The stretchable device according to any one of <1> to <6>, wherein the first cover layer and the second cover layer define a through hole that penetrates the first cover layer and the second cover layer in the discontinuous region.
<9> The stretchable device according to any one of <1> to <8>, further including a resin layer (1) between the first main surface of the stretchable substrate and the stretchable wiring or (2) covering the first main surface and the stretchable wiring, wherein the discontinuous region is defined by the stretchable substrate and the resin layer.
<10> The stretchable device according to any one of <1> to <9>, wherein an inner side surface of the stretchable substrate and an inner side surface of the resin layer define a stepped structure.
<11> The stretchable device according to <10>, wherein the inner side surface of the stretchable substrate is located inside the inner side surface of the resin layer.
<12> The stretchable device according to <10>, wherein the inner side surface of the stretchable substrate is located outside the inner side surface of the resin layer.
<13> The stretchable device according to any one of <1> to <12>, wherein the first cover layer and the second cover layer are connected to each other with an adhesive layer interposed therebetween in the discontinuous region in the thickness direction of the stretchable substrate.
<14> The stretchable device according to any one of <1> to <12>, wherein the first cover layer and the second cover layer are in contact with each other in the discontinuous region in the thickness direction of the stretchable substrate.
<15> The stretchable device according to any one of <1> to <14>, wherein the stretchable wiring is a plurality of stretchable wirings, the plurality of stretchable wirings are separately opposed to one another, and the connection portion between the first cover layer and the second cover layer is between a pair of adjacent stretchable wirings of the plurality of stretchable wirings.
<16> The stretchable device according to <15>, wherein the connection portion is a plurality of connection portions, and each of the plurality of connection portions is respectively disposed between alternating pairs of adjacent stretchable wirings among each of the plurality of stretchable wirings.
<17> The stretchable device according to any one of <1> to <16>, wherein a total planar size of the discontinuous region is 10% to 90% of a planar size of the stretchable substrate as viewed in the thickness direction of the stretchable substrate.
<18> The stretchable device according to any one of <1> to <17>, wherein elastic moduli of the first cover layer and the second cover layer are smaller than an elastic modulus of the stretchable substrate.
<19> The stretchable device according to any one of <1> to <18>, wherein a connection surface between the first cover layer and the second cover layer overlaps an inside of the discontinuous region in the thickness direction of the stretchable substrate.
<20> The stretchable device according to any one of <1> to <19>, wherein the connection surface is between both the first main surface and the second main surface of the stretchable substrate in a sectional view thereof.

### DESCRIPTION OF REFERENCE SYMBOLS

100, 101 to 108: Stretchable device
10: Stretchable substrate
11: First main surface
12: Second main surface
14: Inner side surface
20: Stretchable wiring
30: First cover layer
40: Second cover layer
50: Connection portion between first cover layer and second cover layer
51: End surface of connection portion
52: Connection surface (or contact surface)
55: Through hole
60: Discontinuous region
61: Contour portion of discontinuous region
70, 70a: Resin layer
71, 71a: Inner side surface
80: Adhesive layer
W: Width dimension of connection portion
X: Thickness direction of stretchable substrate

1. A stretchable device comprising:
a stretchable substrate having a first main surface and a second main surface;
stretchable wiring adjacent the first main surface;
a first cover layer covering the first main surface and the stretchable wiring; and
a second cover layer covering the second main surface,
wherein at least the stretchable substrate includes a discontinuous region, and the first cover layer and the second cover layer are connected to each other in the discontinuous region.

2. The stretchable device according to claim 1, wherein a connection portion between the first cover layer and the second cover layer connected to each other covers a contour portion of the discontinuous region.

3. The stretchable device according to claim 1, wherein the first cover layer and the second cover layer form a laminated structure in the discontinuous region.

4. The stretchable device according to claim 1, wherein the connection portion between the first cover layer and the second cover layer connected to each other is located inside the contour portion of the discontinuous region.

5. The stretchable device according to claim 1, wherein the first cover layer and the second cover layer overlap in at least a part of the discontinuous region as viewed from a thickness direction of the stretchable substrate.

6. The stretchable device of claim 5, wherein the first cover layer and the second cover layer overlap along a contour portion of the discontinuous region.

7. The stretchable device according to claim 1, wherein the connection portion between the first cover layer and the second cover layer is located in the entire discontinuous region as viewed from the thickness direction of the stretchable substrate.

8. The stretchable device according to claim 1, wherein the first cover layer and the second cover layer define a through hole that penetrates the first cover layer and the second cover layer in the discontinuous region.

9. The stretchable device according to claim 1, further comprising a resin layer (1) between the first main surface of the stretchable substrate and the stretchable wiring or (2) covering the first main surface and the stretchable wiring, and wherein the discontinuous region is defined by the stretchable substrate and the resin layer.

10. The stretchable device according to claim 9, wherein an inner side surface of the stretchable substrate and an inner side surface of the resin layer define a stepped structure.

11. The stretchable device according to claim 10, wherein the inner side surface of the stretchable substrate is located inside the inner side surface of the resin layer.

12. The stretchable device according to claim 10, wherein the inner side surface of the stretchable substrate is located outside the inner side surface of the resin layer.

13. The stretchable device according to claim 1, wherein the first cover layer and the second cover layer are connected to each other with an adhesive layer interposed therebetween in the discontinuous region in the thickness direction of the stretchable substrate.

14. The stretchable device according to claim 1, wherein the first cover layer and the second cover layer are in contact with each other in the discontinuous region in the thickness direction of the stretchable substrate.

15. The stretchable device according to claim 1, wherein the stretchable wiring is a plurality of stretchable wirings, the plurality of stretchable wirings are separately opposed to one another, and the connection portion between the first cover layer and the second cover layer is between a pair of adjacent stretchable wirings of the plurality of stretchable wirings.

16. The stretchable device according to claim 15, wherein the connection portion is a plurality of connection portions, and each of the plurality of connection portions is respectively disposed between alternating pairs of adjacent stretchable wirings among each of the plurality of stretchable wirings.

17. The stretchable device according to claim 1, wherein a total planar size of the discontinuous region is 10% to 90% of a planar size of the stretchable substrate as viewed in the thickness direction of the stretchable substrate.

18. The stretchable device according to claim 1, wherein elastic moduli of the first cover layer and the second cover layer are smaller than an elastic modulus of the stretchable substrate.

19. The stretchable device according to claim 1, wherein a connection surface between the first cover layer and the second cover layer overlaps an inside of the discontinuous region in the thickness direction of the stretchable substrate.

20. The stretchable device according to claim 19, wherein the connection surface is between both the first main surface and the second main surface of the stretchable substrate in a sectional view thereof.
